(19) United States
(12) Patent Application Publication
(10) Pub. No.: US 2011/0170033 A1
(43) Pub. Date: Jul. 14, 2011

(54) LIQUID CRYSTAL DISPLAY DEVICE AND MANUFACTURING METHOD THEREFOR

(75) Inventor: Takushi Mihotani, Osaka (JP)

(73) Assignee: SHARP KABUSHIKI KAISHA, Osaka (JP)

(21) Appl. No.: 13/119,177

(22) PCT Filed: Jun. 3, 2009
(86) PCT No.: PCT/JP2009/060146

§ 371 Date: Mar. 15, 2011

(30) Foreign Application Priority Data
Sep. 25, 2008 (JP) 2008-246507
Apr. 2, 2009 (JP) 2009-090162

(51) Int. Cl. G02F 1/13357; H05K 13/00

(52) U.S. Cl. 349/58; 29/592.1

(57) ABSTRACT

Provided is a liquid crystal display device that can be manufactured inexpensively by allowing easy, proper installation of additional light sources, and the manufacturing method for the same. The liquid crystal display device (1) includes a liquid crystal panel (2) having a CF substrate (4) and an array substrate (5) (a pair of substrates). The display device further includes an LED (a light source) (9), and a light guide plate (10) disposed so as to receive the light from the LED (9) and so as to face the liquid crystal panel (2), for projecting the incident light to the liquid crystal panel (2). The array substrate (5) includes a mounting section (5b) for mounting the LED (9) in a manner that the LED (9) faces the light guide plate (10).

### TECHNICAL FIELD

The present invention relates to a display device for displaying characters and images and a method for manufacturing the same.

### BACKGROUND ART

In recent years, flat panel displays, which are thinner and weigh less than conventional cathode-ray tubes, have widely been in use for devices such as liquid crystal televisions, monitors, and portable phones. Such liquid crystal display devices include an illumination unit (backlight) that emits light to the liquid crystal panel, and a liquid crystal panel, which controls the amount of the light passing through it, like a camera shutter, to display desired images.

An example of technologies disclosed for those conventional liquid crystal display devices is Patent Document 1, in which the light source LEDs are mounted on flexible substrates connected to the liquid crystal panel. The flexible substrates are bent about 180 degrees so that the LEDs face the light guide plate, which guides the light from the LED to the liquid crystal panel. This conventional liquid crystal display device uses a holder plate to hold the flexible printed circuits in place. This conventional liquid crystal display also employs a protrusion on the holder plate. The flexible substrates are guided along this protrusion for effective alignment of the light axis of the LED to approximately the center of the light-receiving surface of the light guide panel.

### RELATED ART DOCUMENTS

### Patent Documents

Patent Document 1: Japanese Patent Application Laid-Open Publication No. 2005-326454

### SUMMARY OF THE INVENTION

### Problems to be Solved by the Invention

However, in the technology described above, the flexible substrates, on which LEDs (light source) are mounted, are bent and abutted against the protrusion disposed on the holder plate to facilitate alignment of the LED against the light guide plate. The bending of the flexible printed circuits and installation of the holder plate require high precision, which results in extra time and processes necessary for the alignment of the LED and the light guide plate. Such additional complications in the manufacturing process as well as the increase in the number of parts, by inclusion of the holder plate, make it difficult to control the manufacturing cost.

In particular, this conventional liquid crystal display device requires additional protrusions for additional LEDs, meaning that for every additional protrusion or LED, alignment against the light guide plate is necessary. Therefore, when additional LEDs are used, it can take significantly more time and more effort for alignment of the LEDs and the light guide plate, thereby causing significant increase in manufacturing costs of the liquid crystal display device.

Depending on the sizes and the relative positions of the liquid crystal panel and the light guide plate, longer flexible substrates and/or special size LEDs, which are different from regular, off-the-shelf LEDs, are necessary to appropriately direct the light to the light guide plate. This also increases the manufacturing cost.

The present invention was devised in consideration of the issues described above, and is aiming at providing a liquid crystal display device that can be manufactured inexpensively by allowing easy, proper installation of additional light sources, and a manufacturing method for the same.

### Means of Solving the Problems

To achieve such objectives, the liquid crystal display device of the present invention has a liquid crystal panel having a pair of substrates, a light source, a light guide plate disposed opposite to the liquid crystal panel, which light guide plate receives the light from the light source and redirects the light to the liquid crystal panel, and a light source mounting section provided on one of the pair of substrates, for mounting the light source in such a manner as to place the light source opposite to the light guide plate.

The liquid crystal display device described above has a mounting section on one of the pair of substrates for mounting the light source in such a manner as to place the light source opposite to the light guide plate. This configuration, unlike the conventional device described above, can provide a liquid crystal display device that can be manufactured inexpensively by allowing easy, proper installation of additional light sources.

In the aforementioned liquid crystal display device, it is preferable that one of the pair of substrates has a flat area, on which the effective display region of the liquid crystal panel is formed, and the aforementioned mounting section protrudes continuously from this flat area by a predetermined distance towards the light guide plate.

In this configuration, the light source and the light guide plate are properly aligned and mounted, and one of the pair of substrates is prevented from being oversized.

In the aforementioned liquid crystal display device, the mounting section may have a recess.

In this case, the space available for electronic components on the mounting section can be increased.

In the aforementioned liquid crystal display device, the size of the aforementioned mounting section may be determined by the space available for the light source.

In this case, the mounting precision of the light source onto the mounting section can be easily improved.

In the aforementioned liquid crystal display device, one of the pair of substrates is preferably an array substrate for liquid crystal display devices.

In this case, the mounting section can be provided on the backside of the terminal section on which wirings for driving the liquid crystal layer are disposed. Providing the mounting section on the backside of the terminal section is easier than providing the mounting section on the other one of the pair of substrates.

In the aforementioned liquid crystal display device, the aforementioned array substrate is preferably an active matrix driver circuit substrate.

In this case, a high-performance liquid crystal display device can be easily constituted.

In the aforementioned liquid crystal display device, one end of the aforementioned light guide plate preferably abuts against the aforementioned mounting section.

In this case, the alignment of the light guide plate is easy, and the process of the light guide plate installation can be simplified.

In the aforementioned liquid crystal display device, an optical sheet may be disposed between the aforementioned light guide plate and one of the aforementioned pair of substrates, and protrusions may be formed on one of the pair of substrates, which protrusions extend from the aforementioned flat area by a predetermined distance towards the light guide plate, extend continuously from the aforementioned mounting section, and constitute a frame body together with the mounting section. The optical sheet may be disposed inside the frame body.

In this case, the alignment of the optical sheet is easy, and the optical sheet installation process can be simplified.

In the aforementioned liquid crystal display device, the aforementioned light source and the aforementioned light guide plate are preferably disposed with the light-emitting side of the aforementioned light source and the light-receiving side of the aforementioned light guide plate being in contact with each other.

In this case, all the light from the light source enters the light guide plate with minimum light leakage.

In the aforementioned liquid crystal display device, the aforementioned light source is preferably a light-emitting diode.

In this case, a compact liquid crystal display device can be easily constituted.

The manufacturing method for the liquid crystal display device of the present invention is for manufacturing of the liquid crystal display device that includes a liquid crystal panel having a pair of substrates, a light source, and a light guide plate disposed opposite to the liquid crystal panel, which light guide plate receives the light from the light source and redirects the light to the liquid crystal panel. This manufacturing method includes a formation process for forming, on one of the aforementioned pair of substrates, a mounting section for mounting the light source opposite to the light guide plate.

The manufacturing method for the liquid crystal display device described above includes a process for forming a mounting section on one of the pair of substrates, for mounting a light source in such a manner as to place the light source opposite to the light guide plate. This configuration, unlike the conventional device described above, can provide a liquid crystal display device that can be manufactured inexpensively by allowing easy, proper installation of additional light sources.

In the aforementioned formation process in the manufacturing method for the aforementioned liquid crystal display device, the aforementioned mounting section preferably protrudes continuously from the flat area on which the effective display region of the aforementioned liquid crystal panel is formed, wherein the mounting section protrudes towards the aforementioned light guide plate by a predetermined distance.

In this case, the light source and the light guide plate are properly aligned, and one of the pair of substrates is prevented from being oversized.

In the aforementioned formation process in the manufacturing method of the aforementioned liquid crystal display device, a recess may be formed on the aforementioned mounting section.

In this case, the space available for electronic components on the mounting section can be increased.

In the aforementioned formation process in the manufacturing method for the aforementioned liquid crystal display device, the size of the aforementioned mounting section may be determined by the space available for the aforementioned light source.

In this case, the mounting precision of the light source onto the mounting section can be easily improved.

In the aforementioned formation process in the manufacturing method for the aforementioned liquid crystal display device, the aforementioned mounting section is preferably formed on one of the aforementioned pair of substrates by wet etching.

In this case, the mounting section can be easily formed on one of the pair of substrates.

In the aforementioned formation process in the manufacturing method for the aforementioned liquid crystal display device, the aforementioned mounting section may be formed on one of the aforementioned pair of substrates by using a mask made of UV curable heat-separating resin.

In this case, the etchant used in the wet etching is prevented from permeating excessively into one of the pair of substrates, which enables high-precision formation of the mounting section. After the mounting section formation, the mask can easily be removed.

In the manufacturing method of the aforementioned liquid crystal display device, it is preferable that:

prior to the aforementioned formation process, a panel formation process is conducted, in which a plurality of the aforementioned liquid crystal panels are formed as one piece;

in the aforementioned formation process, the border area between two adjacent liquid crystal panels, near the aforementioned mounting section, is made to have a uniform thickness; and

after the formation process, a cutting process is conducted, in which the aforementioned plurality of liquid crystal panels are individually separated by cutting through the border area with a scriber.

In this case, low-cost mass production of the liquid crystal display device, in which the light source is properly disposed, can easily be conducted.

In the manufacturing method of the aforementioned liquid crystal display device, it is preferable that:

prior to the aforementioned formation process, the panel formation process is conducted, in which a plurality of the aforementioned liquid crystal panels are formed as one piece;

in the aforementioned formation process, protrusions are formed on one of the aforementioned pair of substrates, which protrusions extend from the aforementioned flat area by a predetermined distance towards the aforementioned light guide plate, and are formed continuously from the aforementioned mounting section to constitute, together with the mounting section, a frame body;

after the aforementioned formation process, a cutting process is conducted, in which the aforementioned plurality of liquid crystal panels are individually separated by cutting through the frame body with a scriber; and

after the aforementioned cutting process, an installation process is conducted, in which a predetermined optical sheet is disposed inside the frame body of individually separated liquid crystal panels.

In this case, low-cost mass production of the liquid crystal display device, in which the light source and the optical sheet are properly disposed, can be easily conducted.

In the manufacturing method for the aforementioned liquid crystal display device, the aforementioned light source and the aforementioned light guide plate are preferably disposed on the mounting section formed in the aforementioned formation process, with the light-emitting side of the aforementioned light source and the light-receiving side of the aforementioned light guide plate being in contact with each other.

In this case, all the light from the light source enters the light guide plate, with minimum light leakage.

In the manufacturing method for the aforementioned liquid crystal display device, an installation process is preferably conducted, in which light-emitting diodes as the light source are disposed on the aforementioned mounting section formed in the aforementioned formation process.

In this case, a compact liquid crystal display device can be easily constituted.

### EFFECTS OF THE INVENTION

The present invention can provide a liquid crystal display device that can be manufactured inexpensively by allowing easy, proper installation of additional light sources, and a manufacturing method for the same.

### BRIEF DESCRIPTION OF THE DRAWINGS

FIG. 1 is a view that explains a liquid crystal display device according to Embodiment 1 of the present invention.

FIG. 2 is a plan view of an array substrate shown in FIG. 1, and illustrates the arrangement of main components of the array substrate.

FIG. 3 is a view that explains a specific example of the switching elements disposed on the array substrate.

FIG. 4 is an enlarged side view of the aforementioned array substrate, LEDs, and the light guide plate, in which the relationship of these elements is illustrated.

FIG. 5 (a) to FIG. 5 (c) are views that explain a manufacturing method for the liquid crystal display device according to Embodiment 2 of the present invention.

FIG. 6 (a) and FIG. 6 (b) are views that explain a manufacturing process for the liquid crystal display device, conducted sequentially after the process shown in FIG. 5 (c).

FIG. 7 is a view that explains a liquid crystal display device according to Embodiment 3 of the present invention.

FIG. 8 is a plan view of the array substrate shown in FIG. 7, and illustrates an arrangement of main components of the array substrate.

FIG. 9 is a view that explains a manufacturing process for the liquid crystal display device shown in FIG. 7.

FIG. 10 is a plan view of an array substrate of the liquid crystal display device according to Embodiment 4 of the present invention, which shows the arrangement of main components of the array substrate.

FIG. 11 is an enlarged side view of the array substrate shown in FIG. 10, LED and a light guide plate, and illustrates the relationship of these elements.

FIG. 12 is a plan view of an array substrate of a liquid crystal display device according to Embodiment 5 of the present invention, which shows the arrangement of main components of the array substrate.

FIG. 13 is a view that explains a liquid crystal display device according to Embodiment 6 of the present invention.

FIG. 14 is a plan view of the array substrate shown in FIG. 13, and illustrates the arrangement of main components of the array substrate.

FIG. 15 is an enlarged side view of the array substrate shown in FIG. 13, LED and a light guide plate, and illustrates the relationship of these elements.

FIG. 16 is a view that explains a liquid crystal display device according to Embodiment 7 of the present invention.

FIG. 17 is a plan view of the array substrate shown in FIG. 16, and illustrates the arrangement of main components of the array substrate.

FIG. 18 is a view that explains the manufacturing process for the liquid crystal display device shown in FIG. 16.

### DETAILED DESCRIPTION OF EMBODIMENTS

Preferred embodiments of the liquid crystal display device of the present invention and manufacturing methods of the embodiments are described below with reference to the figures. In the examples described below, the present invention is illustrated as applied to a transmissive liquid crystal display device. Dimensions of members shown in the figures may not accurately represent the actual dimensions or the actual dimensional ratio of the members.

### Embodiment 1

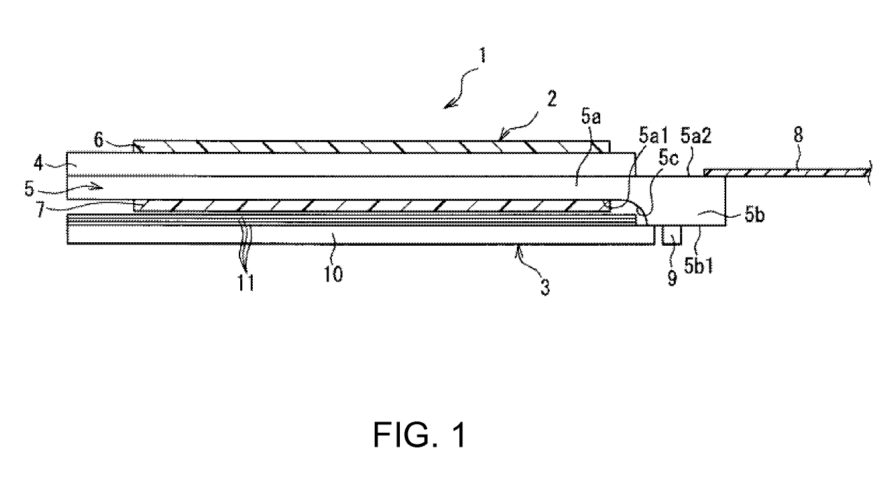

FIG. 1 is a view that explains the liquid crystal display device according to Embodiment 1 of the present invention. In FIG. 1, a liquid crystal display device 1 of this embodiment has a liquid crystal panel 2 and illumination unit 3. In FIG. 1, the top side of the liquid crystal panel 2 is the viewer's side (side of the display surface), and the illumination unit 3 is disposed on the non-display surface side (the down side in FIG. 1) of the liquid crystal panel 2, illuminating the liquid crystal panel 2.

The liquid crystal panel 2 has a pair of substrates, which are a CF (Color Filter) substrate 4 and an array substrate 5, and polarizing plates 6 and 7 disposed on the outer surfaces of the CF substrate 4 and the array substrate 5, respectively. A liquid crystal layer (not shown) is held between the CF substrate 4 and the array substrate 5. The CF substrate 4 and array substrate 5 are formed of transparent material, such as glass.

The array substrate 5, one of the pair of substrates and also called a TFT substrate, is an active matrix driver circuit substrate. That is, the array substrate 5 has pixel electrodes and TFTs (Thin Film Transistors) formed on the side of the array substrate 5 facing the liquid crystal layer (not shown), in which the pixel electrodes and TFTs correspond to individual pixels contained in the effective display region of the display surface of the liquid crystal panel 2. The CF substrate 4, on the other hand, the other of the pair of substrates, has color filters and an opposite electrode formed on the side of the CF substrate 4 facing the liquid crystal layer (not shown).

The array substrate 5 has a larger dimension than the CF substrate 4 in the horizontal direction in FIG. 1. As described later, the array substrate 5 has a terminal section, on which wirings for connection to elements such as the TFTs are disposed, and a mounting section for disposing LEDs.

The CF substrate 4 and array substrate 5 may be made of transparent synthetic resin, such as acrylic resin.

The liquid crystal panel 2 has FPC (Flexible Printed Circuit) 8 connected to a control unit (not shown) that drives the liquid crystal panel 2. By operating the liquid crystals on a pixel by pixel basis, an effective display region is driven on a pixel by pixel basis to display desired images on the effective display region.

An illumination unit 3 has a light source LED (light emitting diode) 9 and a light guide plate 10, which is disposed as opposed to the LED 9. The light guide plate 10 of the illumination unit 3 is coupled to the liquid crystal panel 2 such that the liquid crystal panel 2 is disposed above the light guide plate 10. The illumination unit 3 is integrated with the liquid crystal panel 2 to constitute a transmissive liquid crystal display device 1, in which illumination light from the illumination unit 3 enters the liquid crystal panel 2.

The light guide plate 10 is formed of a transparent synthetic resin, such as acrylic resin. Light from the LED 9 enters the light guide plate 10. Optical sheets 11, such as lens sheets or diffuser sheets, are disposed on the light guide plate 10, on the side facing the liquid crystal panel 2 (the light emitting side). The light from the LED 9 enters the light guide plate 10 (in FIG. 1, this light path is from right to left), and is guided in predetermined directions through the light guide plate 10. This light is then converted as it passes through the optical sheet 11 to a planar illumination light having a uniform luminance, and proceeds to the liquid crystal panel 2.

As shown in FIG. 1, the right end of the light guide plate 10 extends to a mounting section described later, and abuts against the mounting section. In this embodiment, this enables easy alignment of the light guide plate 10, thereby facilitating the process of coupling the light guide plate 10 to the liquid crystal display device 1 (this holds true for other embodiments described later).

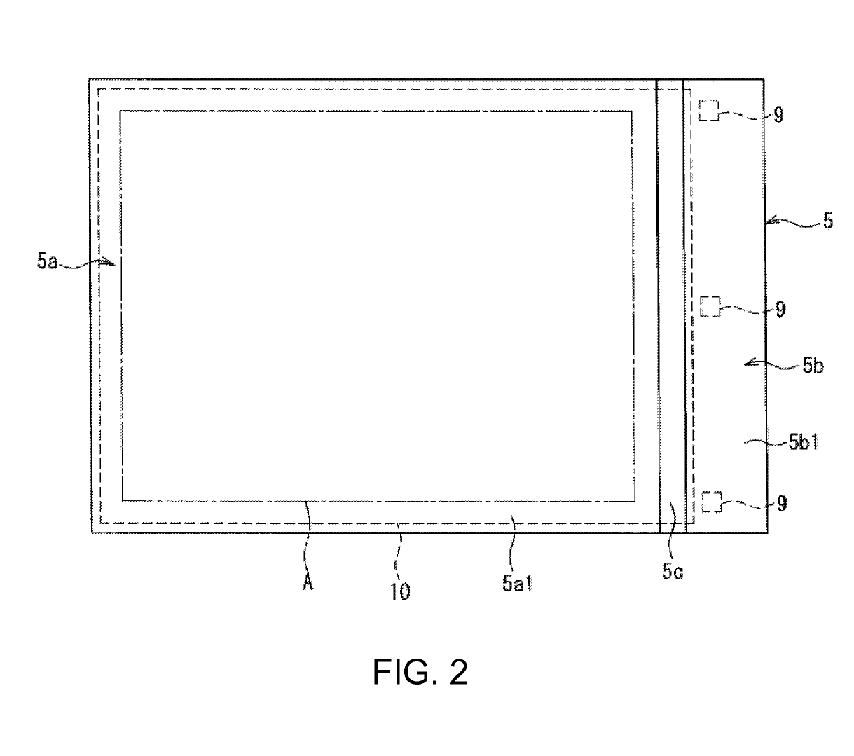

Here, array substrate 5 according to this embodiment is described with reference to FIGS. 2 to 4.

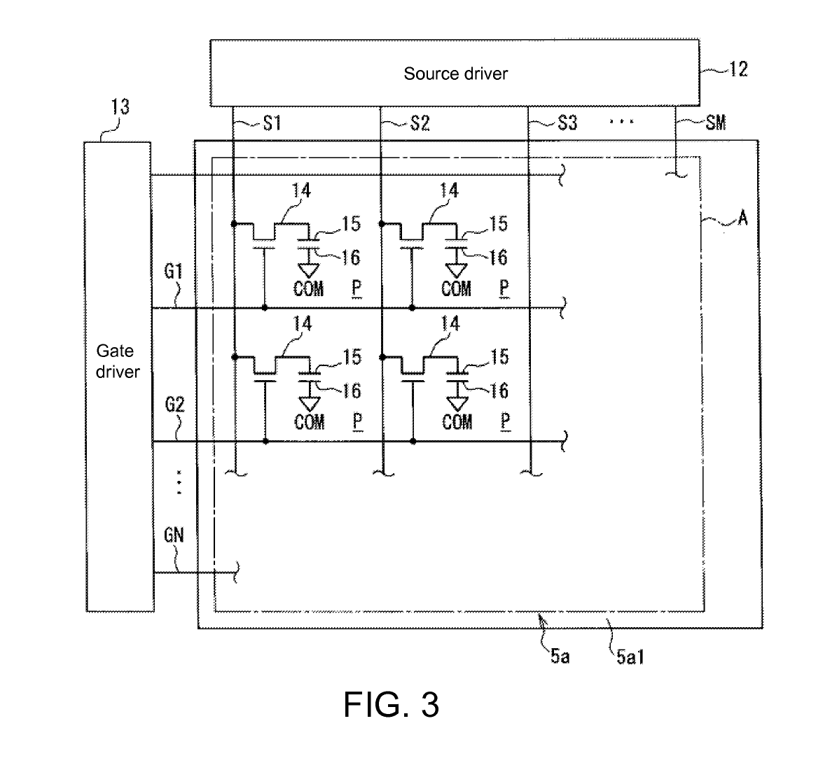

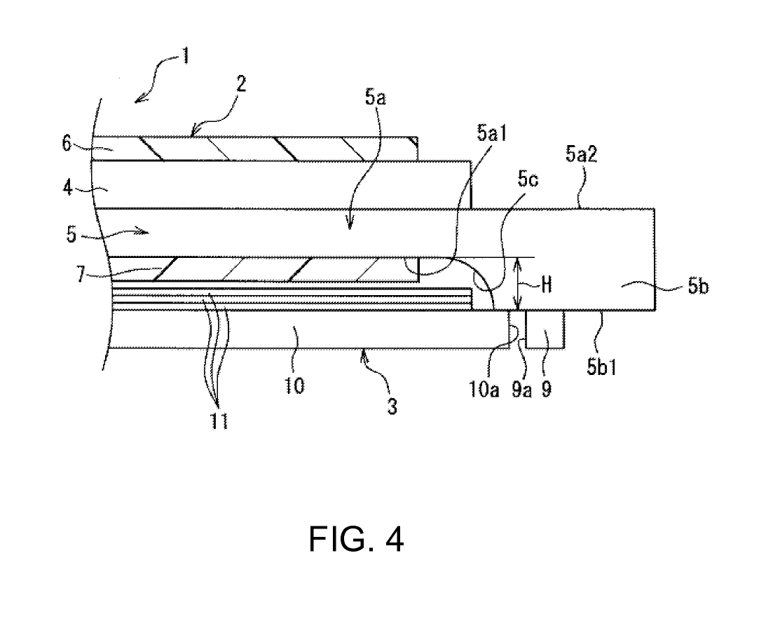

FIG. 2 is a plan view of the array substrate shown in FIG. 1, and illustrates the arrangement of main components of the array substrate. FIG. 3 is a view that explains a specific example of the switching elements disposed on the aforementioned array substrate. FIG. 4 is an enlarged side view of the aforementioned array substrate, the LED, and the light guide plate, in which the relationship of these elements is illustrated.

As shown in FIG. 2, the array substrate 5 has a flat area 5a, on which the aforementioned effective display region A is formed in the area indicated by the alternate long and short dashed line, and a mounting section 5b for mounting, for example, three LEDs 9.

As shown in FIG. 3, the liquid crystal display device 1 has a source driver 12 and a gate driver 13, which operate according to the instruction signals from the aforementioned control unit. The source driver 12 and gate driver 13 are driver circuits that drive a plurality of pixels P on a pixel by pixel basis. To the source driver 12 and gate driver 13, a plurality of source wirings S1 to SM (hereinafter “S”), where “M” denotes an integer of 2 or more, and a plurality of gate wirings G1 to GN (hereinafter “N”), where “N” denotes an integer of 2 or more, disposed on the flat area 5a on the array substrate 5, are connected, respectively. The source driver 12 is configured to send out voltage signals corresponding to external image signals to the source wirings S as source signals. The gate driver 13, on the other hand, is designed to send scan signals sequentially to the gate wirings.

The source wirings S and gate wirings G are arranged in a matrix at least in the effective display region A. The aforementioned plurality of pixels P are each disposed in a compartment arranged in a matrix. The plurality of pixels P include red, green and blue pixels. The red, green and blue pixels are disposed sequentially, for example in this order in parallel with each gate wiring G.

A TFT 14, a switching element, is disposed in each pixel P. The gate wiring G is connected to the gate of the TFT 14, and the source wiring S is connected to the source of the TFT 14. Pixel electrode 15 disposed for each pixel P is connected to the drain of the TFT 14. For each pixel P, common electrode 16 is disposed opposite to the pixel electrode 15, and the aforementioned liquid crystal layer is sandwiched between them.

As shown in FIG. 4, the flat area 5a on the array substrate 5 has surface 5a1 and surface 5a2, which oppose to each other and are both formed flat. Polarizing plate 7 is attached to and combined with the surface 5a1. On the surface 5a2, the aforementioned wirings connecting the FPC 8, the source wiring S and the gate wiring G are patterned. Also on the surface 5a2, a terminal section for disposing the wirings is formed.

The mounting section 5b is where the three LEDs 9 are disposed in such a manner as to place LEDs opposite to the light guide plate 10. The mounting section 5b is formed continuously from the flat area 5a, and protrudes towards the light guide plate 10 by distance H from the flat area 5a. That is, the mounting section 5b has a flat surface 5b1. The surface 5b1 is formed continuously from the surface Sal of the flat area 5a via a curved surface 5c. The LEDs 9 are mounted directly on the surface 5b1. The LEDs 9 are connected to the aforementioned terminal section via wirings (not shown), and receive power from a power supply (not shown) via the terminal section.

Distance H for the array substrate 5, that is, the protrusion height of the mounting section 5b from the flat area 5a, is determined by the thicknesses of the polarizing plate 7 and the optical sheet 11. Specifically, as shown in FIG. 4, the mounting section 5b is formed as a protrusion from the flat area 5a, allowing a light emitting surface 9a of the LED 9 to face a light receiving surface 10a of the light guide plate 10.

The mounting section 5b of the array substrate 5 according to this embodiment is formed by physical grinding with a grinder. In this formation process, a glass material having at least a combined thicknesses of the flat area 5a and the mounting section 5b is physically ground to form the flat surfaces 5a1 and 5b1 and curved surface 5c to provide the flat area 5a and the mounting section 5b.

Although a case in which the curved surface 5c having an R-shaped cross section is formed between the surface Sal and surface 5b1 is described above, this embodiment is not limited to such case. A vertical surface perpendicular to the surface Sal and surface 5b1 or a stepped surface having a stair case-shaped cross section may be formed.

The liquid crystal display device 1 according to this embodiment has, as described above, the mounting section 5b on the array substrate 5 (one of the pair of substrates) for mounting the LED 9 (light source) in such a way as to position the LED 9 opposite to the light guide plate 10. This configuration of the liquid crystal display device 1 according to this embodiment, unlike the aforementioned conventional device, allows proper and easy mounting of any additional LEDs 9. In this embodiment, unlike the aforementioned conventional device, holder plates or special LEDs, which are different from regular, off-the-shelf LEDs, are not necessary. The liquid crystal display device 1, therefore, can be manufactured at a lower cost.

For the liquid crystal display device 1 according to this embodiment, the mounting section 5b protrudes continuously from the flat area 5a towards the light guide plate 10 by the predetermined distance of H. This configuration ensures proper alignment of the LED 9 and the light guide plate 10, and prevents the array substrate 5 from being oversized.

For the liquid crystal display device 1 according to this embodiment, as shown in FIG. 1, the mounting section 5b is formed on the side opposite the surface 5a2 on which the aforementioned terminal section is formed. This means that the terminal section is reinforced by an additional thickness added by the mounting section 5b. Therefore, in the liquid crystal display device 1 according this embodiment, the terminal section is less likely to suffer from cracks and other damage when elements such as FPC 8 are mounted on the terminal section.

### Embodiment 2

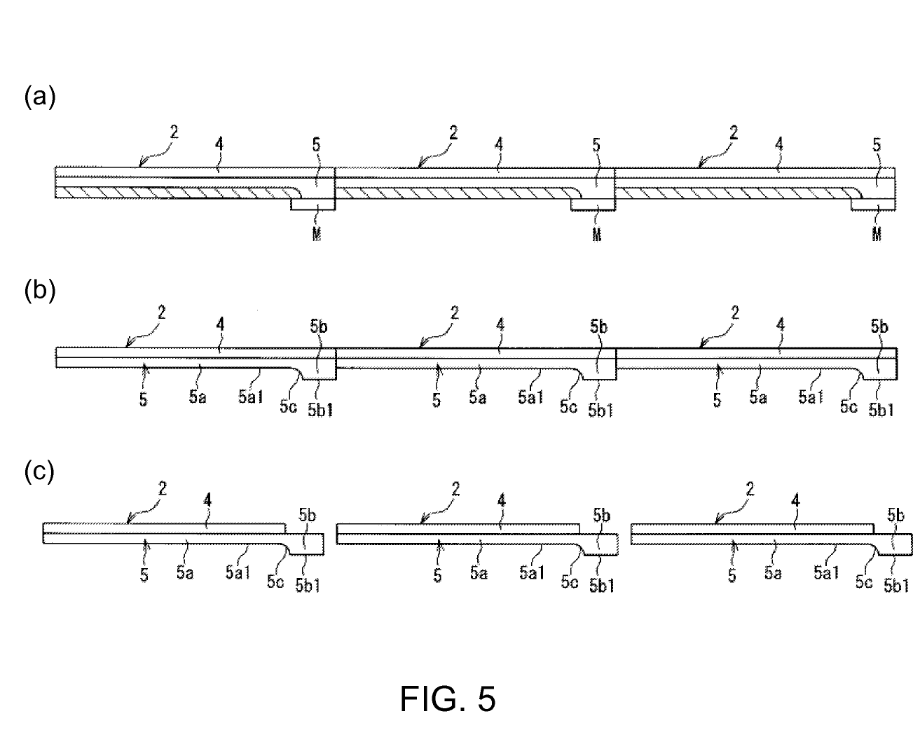

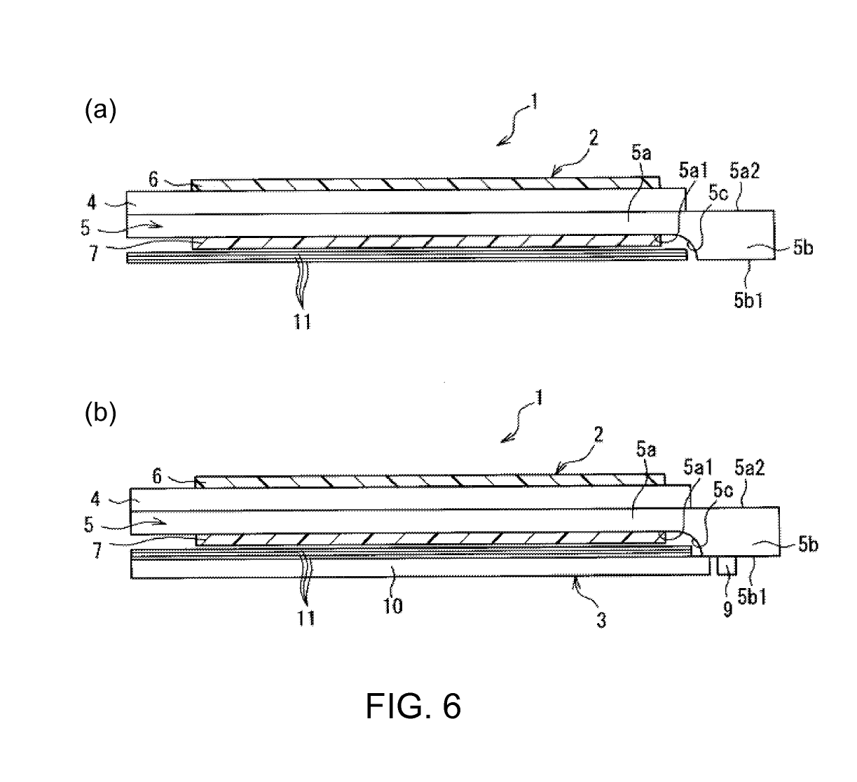

FIG. 5 (a) to FIG. 5 (c) are views that explain the manufacturing method for the liquid crystal display device according to Embodiment 2 of the present invention. FIG. 6 (a) and FIG. 6 (b) are views that explain the manufacturing processes for the liquid crystal display device, sequentially conducted towards the process shown in FIG. 5 (c). The major difference between Embodiment 1 and this embodiment is that, in this embodiment, the mounting section is formed by the wet etching. For elements also referred to in Embodiment 1, the same reference characters are used and redundant descriptions are omitted.

FIG. 5 (a) illustrates this embodiment, in which, for example, three liquid crystal panels 2 are formed as one piece. Specifically, FIG. 5 (a) illustrates a manufacturing stage, in which the panel formation process, where a plurality of liquid crystal panels 2 are formed as one piece, has been completed. That is, the CF substrate 4, on which the color filter layer (not shown) is disposed, and the array substrate 5, on which TFTs 14 are disposed, were bonded together, and the gap between the CF substrate 4 and the array substrate 5 was filled with liquid crystal, to form three liquid crystal panels 2.

As shown in FIG. 5 (a), these liquid crystal panel 2 are subjected to wet etching for the formation of the mounting section 5b. These liquid crystal panels 2 are submerged in the tank (not shown) filled with an etchant, with the right end of each of the array substrates 5 covered with a mask M. This process etches away the shaded portions of the liquid crystal panel 2 in FIG. 5 (a), thinning the entire area except for the portion covered with the mask M.

The next step is shown in FIG. 5 (b), in which the mask M is removed from each of the liquid crystal panels 2, and then the liquid crystal panels 2 are washed and subjected to other processes to form the flat area 5a and the mounting section 5b on the array substrate 5.

In the formation process described above, hydrofluoric acid, for example, is used as the etchant. The mask M is made of, for example, a UV curable heat-separating resin. More specifically, the mask M is made of a UV curable heat-separating resin containing a compound having at least two ethylene unsaturated groups in each molecule, a resin component containing a photopolymerization initiator, and thermally expandable microcapsules. Therefore, the mask M can be easily bonded to a predetermined location on the array substrate 5 by being subjected to UV radiation, and can be easily removed by being submerged in warm water.

Next, as shown in FIG. 5 (c), the three liquid crystal panels 2 are individually separated by a scriber (glass cutter). Then, the right end of the CF substrate 4 of individual liquid crystal panel is cut off, and the aforementioned terminal section is formed on the array substrate 5.

Next, as shown in FIG. 6 (a), on each liquid crystal panel 2, the polarizing plates 6 and 7, and the optical sheet 11 are disposed. Then, as shown in FIG. 6 (b), the light guide plate 10 is disposed beneath the optical sheet 11 and mounted on the mounting section 5b, in such a manner as to place the LED 9 opposite to the light guide plate 10. The liquid crystal display device 1 according to this embodiment is now complete.

With the structure described above, the liquid crystal display device 1 according to this embodiment provides operational advantages that are similar to those of the liquid crystal display device according to Embodiment 1. In this embodiment, unlike in Embodiment 1, the mounting section 5b is formed on the array substrate 5 by wet etching, which is an easier way to form the mounting section 5b on the array substrate 5.

In this embodiment, the mask M, made of UV curable heat-separating resin, is used in the mounting section 5b formation process. The mask M prevents the etchant used in the wet etching from excessively permeating into the array substrate 5, thereby allowing high-precision formation of the mounting section 5b. The mask M can be easily removed after the mounting section 5b is formed.

The mask M may be a protective film or a photoresist such as liquid photoresist and dry film resist instead of such mask described above. In the aforementioned formation process, only the array substrate 5 may be submerged in the etchant to form the mounting section 5b. Also, liquid crystal may be introduced between the CF substrate A and the array substrate 5 after the process of the mounting section 5b formation.

### Embodiment 3

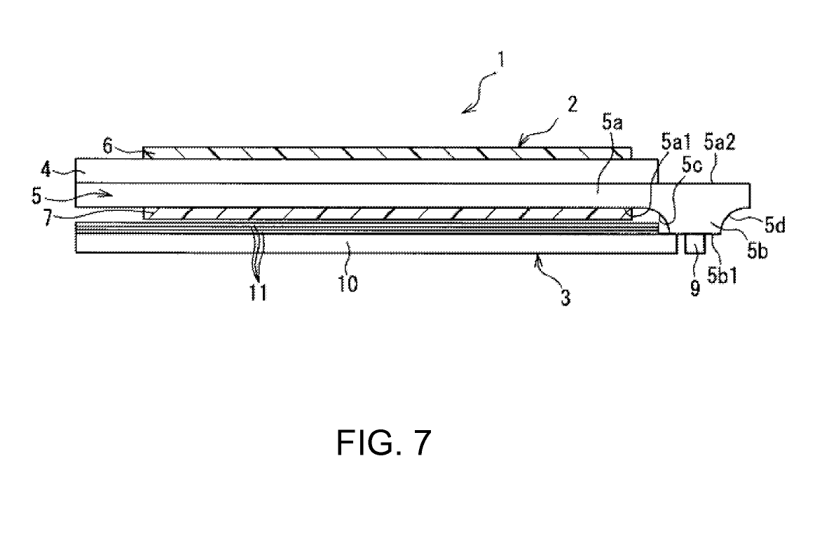

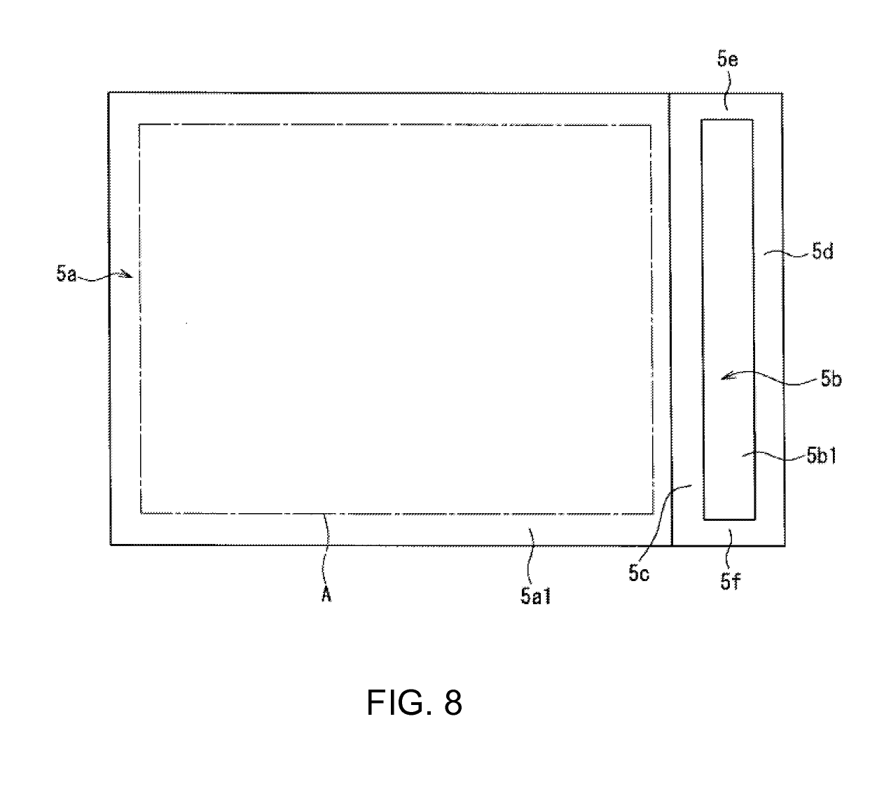

FIG. 7 is a view that explains the liquid crystal display device according to Embodiment 3 of the present invention. FIG. 8 is a plan view of the array substrate shown in FIG. 7, and shows the arrangement of main components of the array substrate. The major difference between Embodiment 2 and this embodiment is that, in this embodiment, the mounting section is reduced to the thickness of the flat area in the area surrounding the mounting section. Here, for elements also referred to in Embodiment 2, the same reference characters are used and redundant descriptions are omitted.

As shown in FIG. 7 and FIG. 8, on the array substrate 5 according to this embodiment, the area surrounding a mounting section 5b is processed to obtain the same thickness as the flat area 5a. Specifically, in this embodiment, a mask M that is smaller than the mask M in

Embodiment 2 is used for formation of the mounting section 5b. As a result, in the process of forming the mounting section 5b in this embodiment, curved surfaces 5c, 5d, 5e and 5f, all having R-shaped cross sections, are formed, and the area surrounding the mounting section 5b reduces to the thickness of the flat area 5a. Therefore, in this embodiment, a plurality of the liquid crystal panels 2, which were originally formed as one piece, can be individually separated by a scriber with a better yield of cutting.

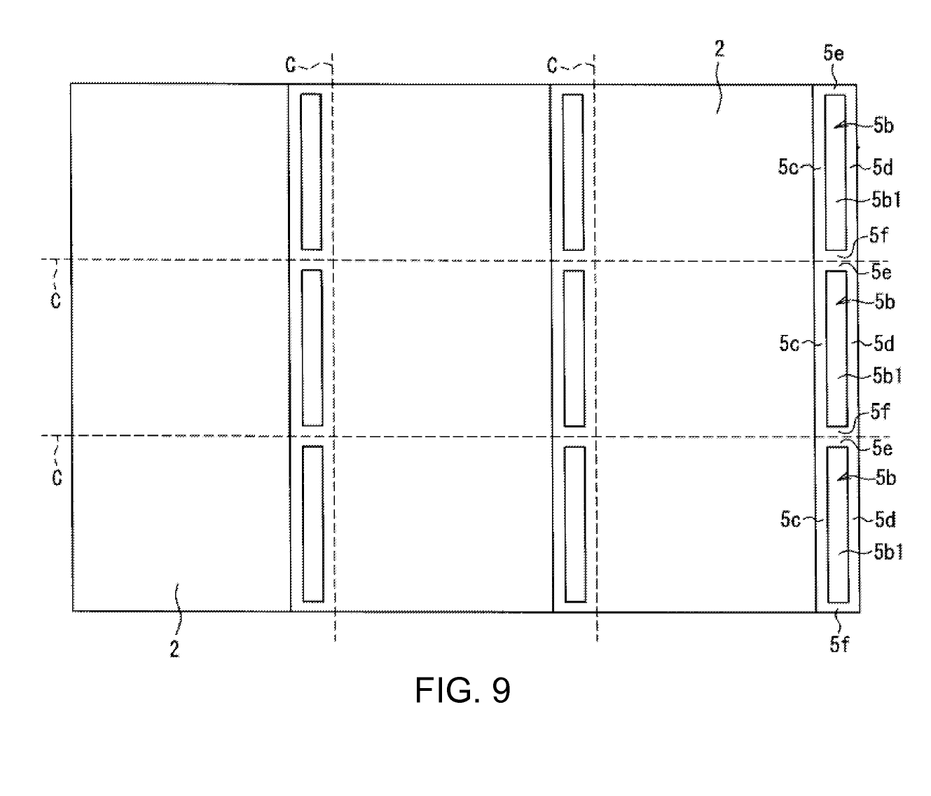

Here, the manufacturing method for the liquid crystal display device 1 according to this embodiment is described with reference to FIG. 9.

FIG. 9 is a view that explains the manufacturing process for the liquid crystal display device shown in FIG. 7.

In this embodiment, as shown in FIG. 9, nine liquid crystal panels 2 are formed in the panel formation process, in which multiple liquid crystal panels 2 are formed as one piece. Then, a formation process using the mask M is performed to form the mounting section 5b on each liquid crystal panel 2. In this formation process, the thickness of the area along the border lines between adjacent liquid crystal panels 2, near the mounting section 5b, is made uniform, the curved surfaces 5c, 5d, 5e and 5f, are formed to constitute the transition area of the mounting section 5b to reduce the mounting section 5b to the thickness of the flat area 5a at the periphery of the mounting section 5b.

Next, in this embodiment, nine liquid crystal panels 2 are individually separated by a scriber, along the border lines which are represented by dashed lines “C” in FIG. 9. If each liquid crystal panel 2 does not have curved surfaces 5d, 5e or 5f, and the mounting section 5b is not reduced to the thickness of the flat area 5a at the periphery of the mounting section 5b, a level difference of the aforementioned dimension H results between the mounting section 5b and the flat area 5a of the adjacent liquid crystal panel 2. Such level difference disallows separation of individual liquid crystal panels by a scriber. As a result, two adjacent liquid crystal panels 2 need to be separated one panel at a time, along the line that makes the flat area 5a smaller.

In this embodiment, since the mounting section 5b is reduced to the thickness of the flat area 5a at the periphery of the mounting section 5b, the liquid crystal panels 2 can be separated with a better yield of cutting, without making the flat area 5a smaller.

With the structure described above, the liquid crystal display device 1 according to this embodiment provides operational advantages that are similar to those of the liquid crystal display device according to Embodiment 2. Also, compared with Embodiment 2, this embodiment provides a better yield of cutting with a scriber by making the border area between the adjacent liquid crystal panels 2, near the mounting section 5b, have a uniform thickness. The uniform thickness of the border area allows easy, low-cost mass production of the liquid crystal display device 1, in which LED 9 is properly disposed.

### Embodiment 4

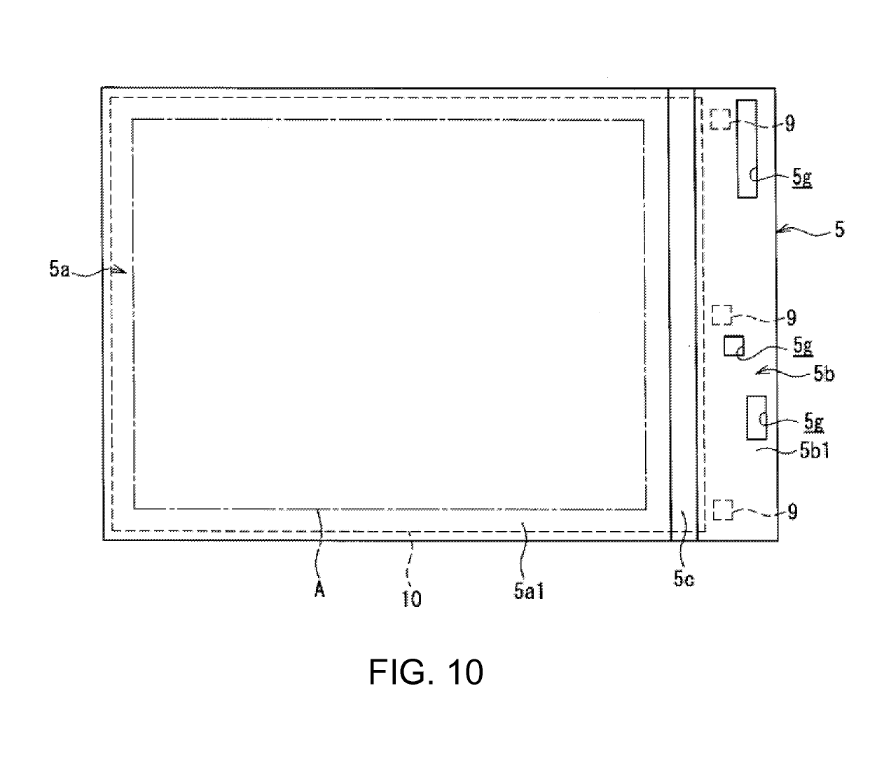

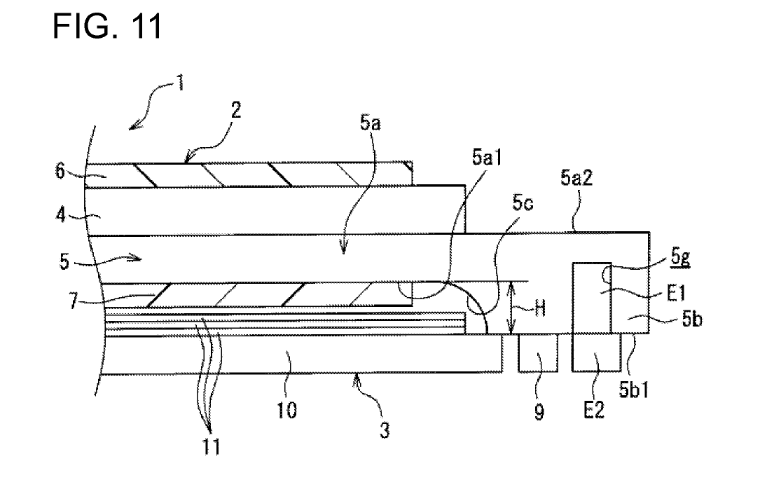

FIG. 10 is a plan view of the array substrate of the liquid crystal display device according to Embodiment 4 of the present invention, in which the arrangement of main components of the array substrate is shown. FIG. 11 is an enlarged side view of the array substrate shown in FIG. 10, LED and the light guide plate, in which the relationship of these elements is illustrated. The major difference between aforementioned Embodiment 1 and this embodiment is that, in this embodiment, a recess is formed in the mounting section. Here, for elements also referred to in Embodiment 1, the same reference characters are used and redundant descriptions are omitted.

That is, as shown in FIG. 10, array substrate 5 of this embodiment has three recesses 5g in the mounting sections 5b. Each of these recesses 5g is formed simultaneously with the mounting section 5b by wet etching, in which the portion that becomes a recess is not covered by the mask M.

As shown in FIG. 11, an electronic component E1 is disposed in the recess 5g. On the surface 5b1, an electronic component E2, which abuts against the electronic component E1, is disposed. The electronic components E1 and E2 are driver circuits (ICs) that drive LEDs 9, for example.

With the structure described above, the liquid crystal display device 1 according to this embodiment provides operational advantages that are similar to those of the liquid crystal display device according to Embodiment 1. In this embodiment, the recesses 5g are formed on the mounting section 5b, which allows an increase in the space available for disposing items such as electronic components on the mounting section 5b.

As in Embodiment 3, in addition to the description above, the mounting section 5b having recesses 5g may be reduced to the thickness of the flat area 5a, at the periphery of the mounting section 5b.

### Embodiment 5

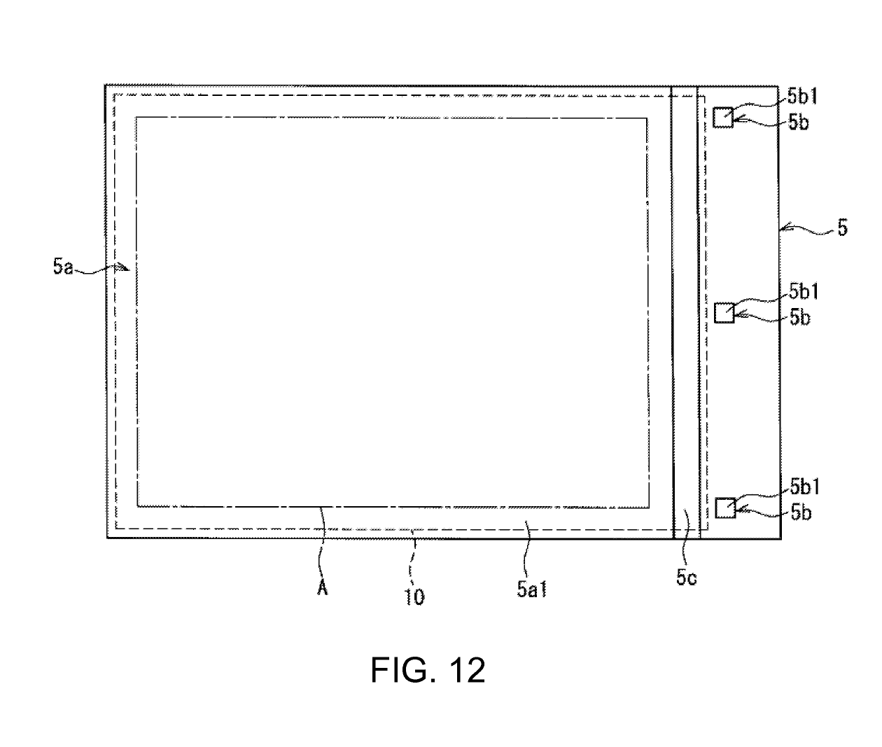

FIG. 12 is a plan view of the array substrate of the liquid crystal display device according to Embodiment 5 of the present invention, in which the arrangement of main components of the array substrate is shown. The major difference between aforementioned Embodiment 1 and this embodiment is that, in this embodiment, the size of the mounting section is determined by the space available for LEDs. Here, for elements also referred to in Embodiment 1, the same reference characters are used and redundant descriptions are omitted.

As shown in FIG. 12, the size of the mounting section 5b on the array substrate 5 according to this embodiment is determined by the space available for the LED 9. That is, in this embodiment, the surface 5b1 of the mounting section 5b is defined as the area that LEDs 9 can be mounted. The mounting section 5b in this embodiment is provided on the array substrate 5, in accordance with the mounting location of the LED 9.

With the structure described above, the liquid crystal display device 1 according to this embodiment provides operational advantages that are similar to those of the liquid crystal display device according to Embodiment 1. Since the size of the mounting section 5b is determined by the space available for the LED 9 (light source) in this embodiment, the mounting precision for mounting the LED 9 to the mounting section 5b can be easily improved. Consequently, this embodiment provides for a higher mounting precision of LED 9 against the light guide plate 10, and therefore, according to this embodiment, a liquid crystal display device 1 featuring highly efficient utilization of light from the LED 9 can be easily constituted.

### Embodiment 6

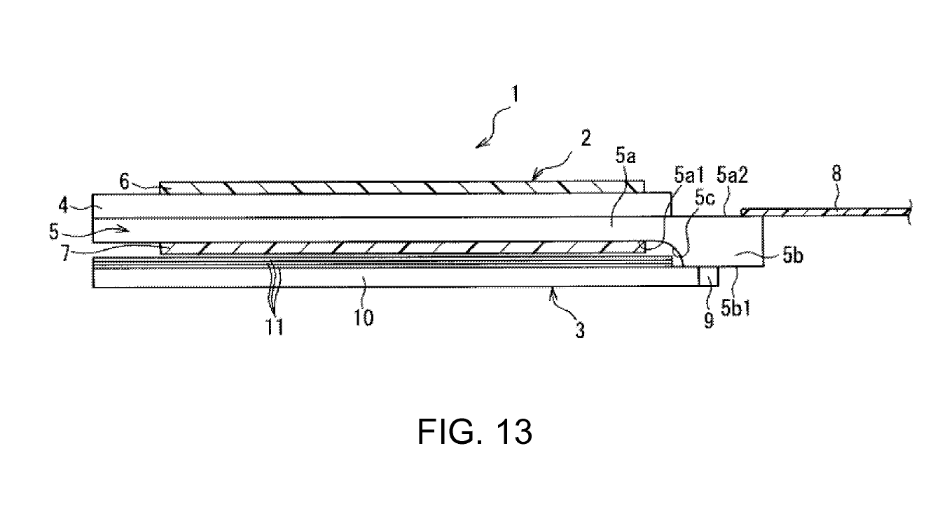

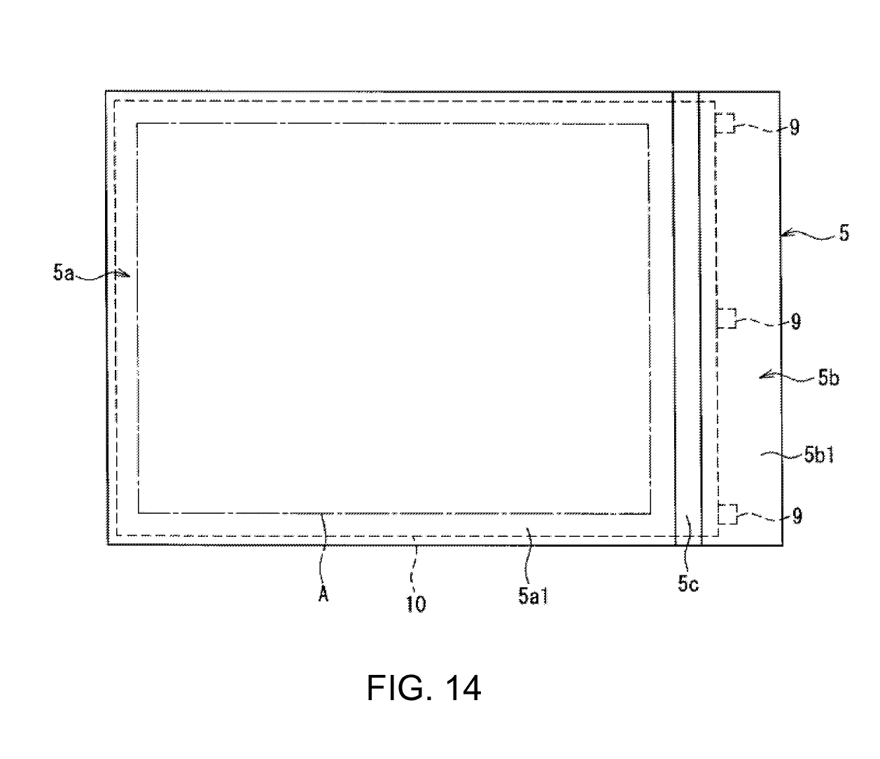

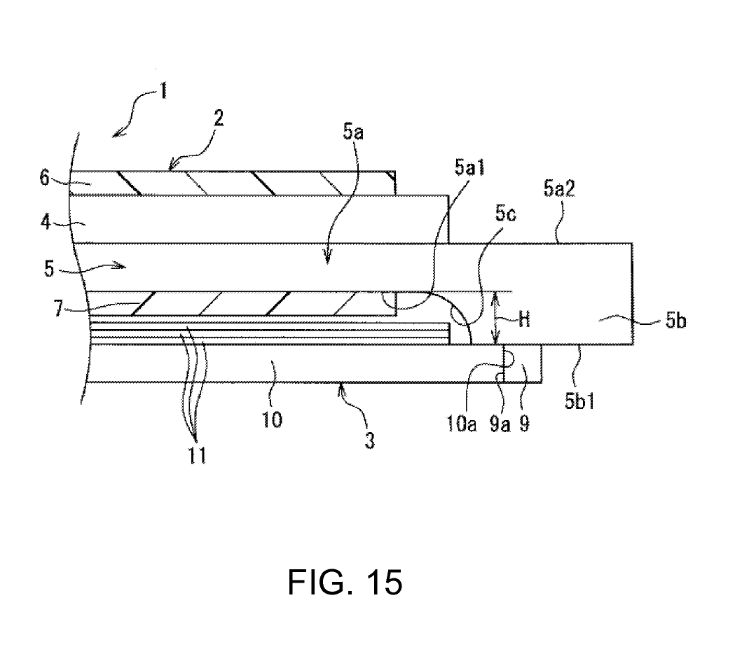

FIG. 13 is a view that explains the liquid crystal display device according to Embodiment 6 of the present invention. FIG. 14 is a plan view of the array substrate shown in FIG. 13, and shows the arrangement of main components of the array substrate is shown. FIG. 15 is an enlarged side view of the array substrate shown in FIG. 13, LED, and the light guide plate, in which the relationship of these elements is illustrated. The major difference between aforementioned Embodiment 1 and this embodiment is that, in this embodiment, the light-emitting surface of the LED and the light-receiving surface of the light guide plate are in contact with each other as they are disposed in place. Here, for elements also referred to in Embodiment 1, the same reference characters are used and redundant descriptions are omitted.

In this embodiment, as shown in FIG. 13 and FIG. 14, the LED 9 is mounted on the mounting section 5b so that the LED 9 is fully in contact with the light guide plate 10. That is, in this embodiment, LED 9 is mounted on the mounting section 5b of the array substrate 5, and is fully in contact with the light guide plate 10, leaving no gap between the LED 9 and the light guide plate 10.

Specifically, as shown in FIG. 15, the LED 9 and the light guide plate 10, in this embodiment, are disposed on the mounting section 5b, with the light-emitting surface 9a of the LED 9 and the light-receiving surface 10a fully in contact with each other. The light guide plate 10 is fixed on the surface 5b1 of the mounting section 5b with, for example, a double-sided tape so that the light guide plate 10 fully contacts the LED 9.

With the structure described above, the liquid crystal display device 1 according to this embodiment provides operational advantages that are similar to those of the liquid crystal display device according to Embodiment 1. In this embodiment, unlike in Embodiment 1, the LED 9 and the light guide plate 10 are disposed on the mounting section 5b, where the light-emitting surface 9a of the LED 9 and the light-receiving surface 10a of the light guide plate are fully in contact with each other. This way, in this embodiment, unlike in Embodiment 1, all the light from the LED 9 enters the light guide plate 10, with minimum light leakage. Therefore, this embodiment eliminates the need of a light-shielding measure for the LED 9, and can easily improve the light utilization efficiency.

This embodiment may be combined with Embodiments 2 to 5 as necessary.

### Embodiment 7

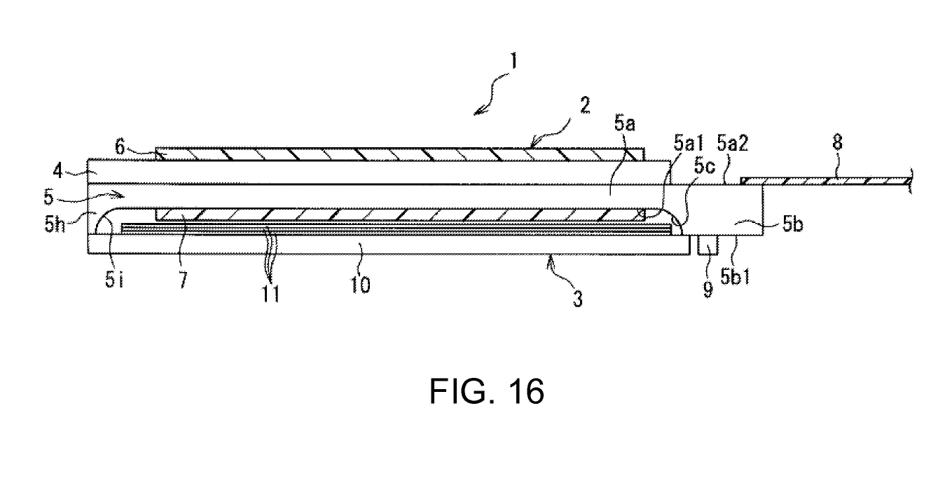

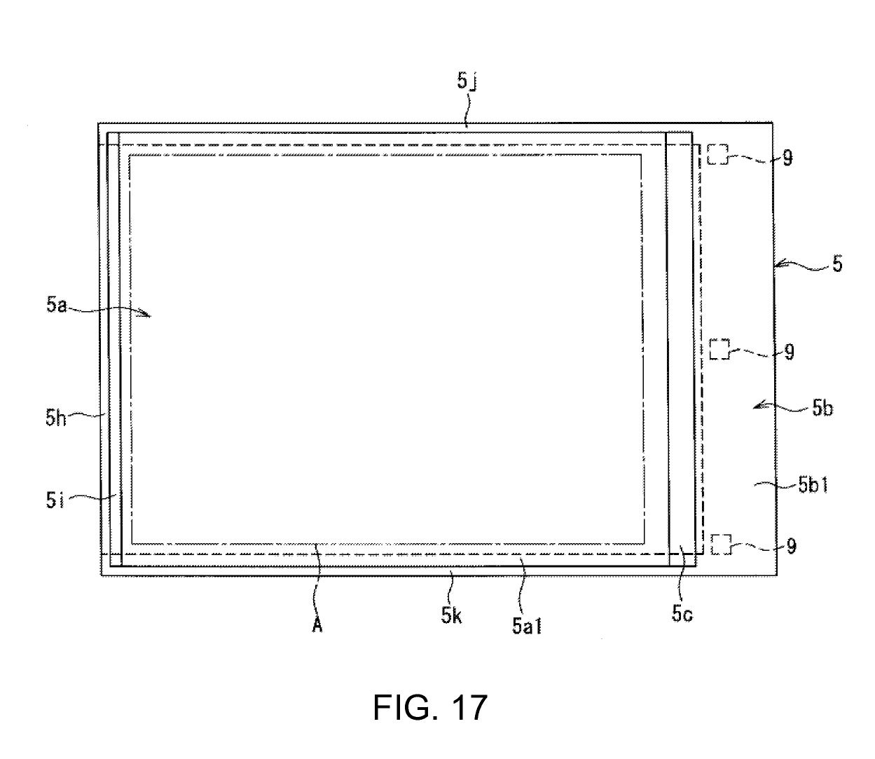

FIG. 16 is a view that explains the liquid crystal display device according to Embodiment 7 of the present invention. FIG. 17 is a plan view of the array substrate shown in FIG. 16, in which the arrangement of main components of the array substrate is illustrated. The major difference between aforementioned Embodiment 1 and this embodiment is that, in this embodiment, a protrusion is formed on the array substrate, which protrusion extends by a predetermined distance from the flat area of the array substrate towards the light guide plate, so as to form a continuous frame body together with the mounting section. Here, for elements also referred to in Embodiment 1, the same reference characters are used and redundant descriptions are omitted.

In this embodiment, as shown in FIG. 16, a protrusion 5h is formed on the array substrate 5 at the left end. The top surface of the protrusion 5h, which is flat, is continuous from the surface 5a1 of the flat area 5a via a curved surface 5i. The protrusion 5h extends a predetermined distance (this is equal to the dimension of the mounting section 5b) from the flat area 5a towards the light guide plate 10. The light guide plate 10 is disposed on the top surface of the protrusion 5h, as well as on the surface 5b1 of the mounting section 5b.

As shown in FIG. 17, array substrate 5 of this embodiment has protrusions 5j and 5k on the top and the bottom locations in the figure. The protrusions 5j and 5k, similar to the protrusion 5h, extend a predetermined distance (this is equal to the dimension of the mounting section 5b) from the flat area 5a towards the light guide plate 10. The protrusions 5j and 5k are formed continuously from the mounting section 5b and the protrusion 5h. In other words, in the array substrate 5 according to this embodiment, the mounting section 5b and the protrusions 5h, 5j, and 5k form a frame body along the perimeter of the liquid crystal panel 2.

As shown in FIG. 16, in the array substrate 5 of this embodiment, the optical sheet 11 is disposed in the aforementioned frame body in addition to the polarizing plate 7, which is directly bonded to the surface Sal of the flat area 5a.

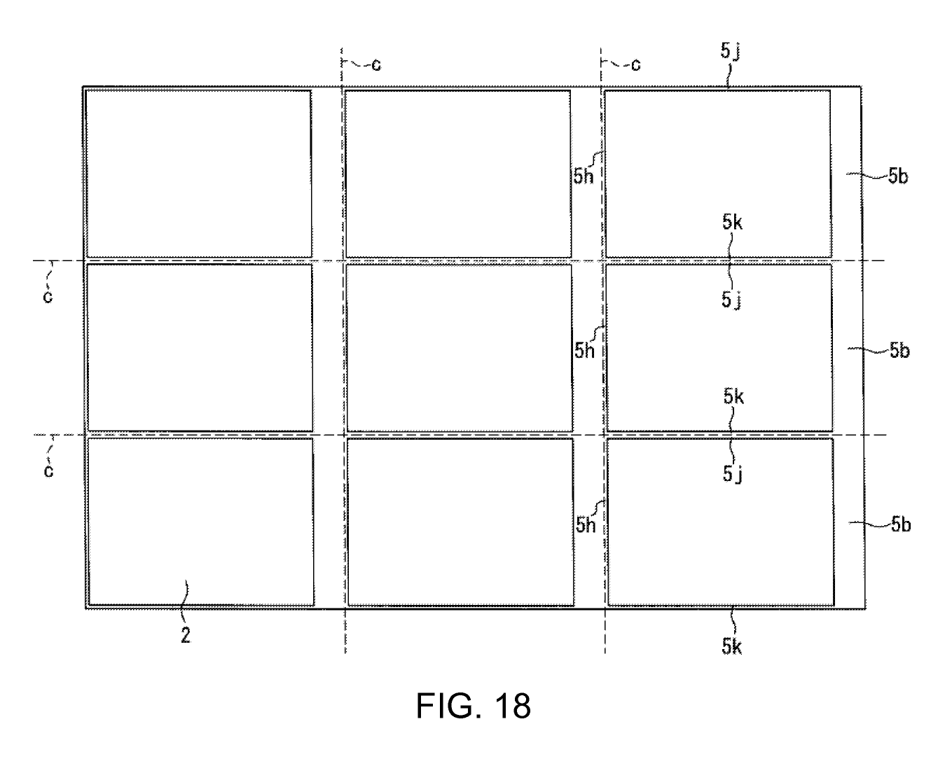

Here, the manufacturing method for the liquid crystal display device 1 according to this embodiment is described with reference to FIG. 18.

FIG. 18 is a view that explains the manufacturing process for the liquid crystal display device shown in FIG. 16.

In this embodiment, as shown in FIG. 18, nine liquid crystal panels 2 are formed in the panel formation process, in which multiple liquid crystal panels 2 are formed as one piece. Then, the mounting section 5b is formed on each liquid crystal panel 2, using a mask (not shown). During this process, protrusions 5h, 5j and 5k, extending from the flat area 5a by a predetermined distance towards the light guide plate 10, are formed. The protrusions 5h, 5j and 5k, together with the mounting section 5b, constitute the aforementioned continuous frame body. In this embodiment, therefore, the aforementioned frame body provides a uniform thickness for the border areas between two adjacent liquid crystal panels 2.

Next, in this embodiment, similar to Embodiment 3, nine liquid crystal panels 2 are individually separated by a scriber, along the border lines which are represented by dashed lines “c” in FIG. 18. That is, similar to Embodiment 3, a plurality of the liquid crystal panels 2, which were originally formed as one piece, can be individually separated by a scriber at a high yield of cutting.

Then, on the individual liquid crystal panel 2 in this embodiment, the polarizing plate 6 is disposed on the CF substrate 4, and the polarizing plate 7 and the optical sheets 11 are disposed inside the aforementioned frame body on the array substrate 5. Then, the light guide plate 10 is installed beneath the optical sheet 11 and mounted on the mounting section 5b, in such a manner as to place the light guide plate 10 opposite to the LED 9. Liquid crystal display device 1 according to this embodiment is now complete.

With the structure described above, the liquid crystal display device 1 according to this embodiment provides operational advantages that are similar to those of the liquid crystal display device according to Embodiment 1. In this embodiment, unlike in Embodiment 1, the mounting section 5b and protrusions 5h, 5j and 5k constitute the aforementioned frame body, and the optical sheet 11 is disposed inside the frame body. This configuration facilitates the alignment of the optical sheet 11. As a result, the installation of the optical sheet 11 is easy in this embodiment. Compared with Embodiment 1, in this embodiment, protrusions 5h, 5j and 5k as well as the mounting section 5b which construct a frame body are formed in the formation process and a better yield of cutting with a scriber is obtained. Thus, this configuration allows an easy, low-cost mass production of the liquid crystal display device 1, in which LED 9 and optical sheet 11 are properly disposed. In this embodiment, unlike in Embodiment 3, protrusions 5h, 5j and 5k are formed, thereby improving the structural strength of the array substrate 5.

This embodiment may be combined with Embodiments 4 and 6 as needed.

It should be noted that the above embodiments are all illustrative and not restrictive. The technological scope of the present invention is defined by the appended claims, and all changes that come within the range of equivalency of the claims are intended to be embraced therein.

For example, in the above description, the present invention is applied to a transmissive liquid crystal display device. However, the present invention is not limited thereto, as long as it is applied to a liquid crystal display device that includes a liquid crystal panel having a pair of substrates.

In the above description, three LEDs are used as the light source. However, the present invention is not limited thereto, as long as a mounting section for mounting the light source is provided on one of the pair of substrates, in such a manner as to place the light source opposite to the light guide plate. The type and the number of the light sources are not limited to those described above. Specifically, the light source may be a discharge tube such as a cold cathode fluorescent tube, which is placed on the mounting section, opposite to the light guide plate.

However, using light-emitting diodes as the light source, as in the embodiments described above, is preferable for easy constitution of compact liquid crystal display devices.

In the above description, although a configuration in which the mounting section is provided on the array substrate, the present invention is not limited thereto. The mounting section may be provided on the CF substrate.

However, the mounting section is preferably provided on the array substrate as in the embodiments described above, because the mounting section can be provided more easily at the backside of the terminal section, on which terminal section wirings connected to the switching elements are disposed, than on the CF substrate.

In the description above, although the array substrate is an active matrix driver circuit substrate, the array substrate of the present invention is not limited thereto, as long as it is for liquid crystal display devices. For example, the array substrate of the present invention may be a simple matrix (STN) array substrate.

However, using an active matrix driver circuit substrate, as in the embodiments described above, is preferable for easy constitution of a high-performance liquid crystal display devices.

In the description above, although light-emitting diodes (light source) are installed after the liquid crystal panels are individually separated by cutting as shown in FIG. 6 (b), the present invention is not limited thereto. For example, the light source may be installed prior to the cutting process.

### INDUSTRIAL APPLICABILITY

The present invention provides a liquid crystal display device that can be manufactured inexpensively by allowing easy, proper installation of additional light sources, and the manufacturing method for the same.

### DESCRIPTION OF REFERENCE CHARACTERS

1 Liquid crystal display device

2 Liquid crystal panel

3 Illumination unit

4 CF substrate (one of the pair of substrates)

5 Array substrate (one of the pair of substrates)

5a Flat area

15b Mounting section

5g Recess

5h, 5j, 5k Protrusion

9 LED (light source)

9a Light emitting surface

10 Light guide plate

10a Light receiving surface

11 Optical sheet

14 TFT (switching element)

A Effective display region

1. A liquid crystal display device having a liquid crystal panel that includes a pair of substrates, comprising a light source and a light guide plate,
wherein said light guide plate receives light from said light source, is disposed opposite to said liquid crystal panel, and redirects the light from said light source towards said liquid crystal panel; and
wherein a mounting section is disposed on one of said pair of substrates for mounting said light source in such a manner as to place said light source opposite to said light guide plate.

2. The liquid crystal display device according to claim 1,
wherein one of said pair of substrates has a flat area on which an effective display region of said liquid crystal panel is formed, and
wherein said mounting section is formed continuously from said flat area, protruding towards said light guide plate by a predetermined distance.

3. The liquid crystal display device according to claim 1, wherein said mounting section has a recess.

4. The liquid crystal display device according to claim 1, wherein a size of said mounting section is determined by a space available for said light source.

5. The liquid crystal display device according to claim 1, wherein one of said pair of substrates is an array substrate for liquid crystal display devices.

6. The liquid crystal display device according to claim 5, wherein said array substrate is an active matrix driver circuit substrate.

7. The liquid crystal display device according to claim 1, wherein an end of said light guide plate abuts against said mounting section.

8. The liquid crystal display device according to claim 2, comprising an optical sheet interposed between said light guide plate and said pair of substrates,
wherein a protrusion is formed on one of said pair of substrates, said protrusion extending from said flat area towards said light guide plate by a predetermined distance and extending continuously from said mounting section to constitute a frame body together with said mounting section; and
wherein said optical sheet is disposed inside said frame body.

9. The liquid crystal display device according to claim 1, wherein said light source and said light guide plate are disposed on said mounting section with a light-emitting side of said light source and a light-receiving side of said light guide plate are in contact with each other.

10. The liquid crystal display device according to claim 1, wherein said light source is a light-emitting diode.

11. A manufacturing method for a liquid crystal display device comprising a liquid crystal panel having a pair of substrates, a light source and a light guide plate, wherein said light guide plate receives light from said light source, is disposed opposed to said liquid crystal panel, and redirects the light from said light source towards said liquid crystal panel, including
a formation process in which a mounting section is formed on one of said pair of substrates for mounting said light source in such a manner as to place said light source opposite to said light guide plate.

12. The manufacturing method for a liquid crystal display device according to claim 11, wherein, in said formation process, said mounting section is continuously formed on a flat area having an effective display region of said liquid crystal panel, said mounting section protruding by a predetermined distance towards said light guide plate.

13. The manufacturing method for a liquid crystal display device according to claim 11, wherein a recess is formed on said mounting section in said formation process.

14. The manufacturing method for a liquid crystal display device according to claim 11, wherein, in said formation process, a size of said mounting section is determined by a space available for said light source.

15. The manufacturing method for a liquid crystal display device according to claim 11, wherein, in said formation process, said mounting section is formed on one of said pair of substrates by wet etching.

16. The manufacturing method for a liquid crystal display device according to claim 15, wherein, in said formation process, said mounting section is formed on one of said pair of substrates by using a mask made of UV curable heat-separating resin.

17. The manufacturing method for a liquid crystal display device according to claim 11, comprising the steps of:
conducting a panel formation process, prior to said formation process, wherein a plurality of said liquid crystal panels are formed as one piece;
conducting said formation process, wherein a thickness of a border area between two adjacent said liquid crystal panels, near said mounting section, is made uniform; and
conducting a separation process, after said formation process, wherein said plurality of liquid crystal panels are individually separated by cutting through said border area with a scriber.

18. The manufacturing method for a liquid crystal display device according to claim 11, comprising the steps of:
conducting a panel formation process, prior to said formation process, wherein a plurality of said liquid crystal panels are formed as one piece;
conducting said formation process, wherein a protrusion is formed on one of said pair of substrates, said protrusion extending from said flat area towards said light guide plate by a predetermined distance and extending continuously from said mounting section to constitute a frame body together with said mounting section;
conducting an installation process, after said formation process, wherein said plurality of liquid crystal panels are individually separated by cutting through said frame body with a scriber; and
conducting a disposition process, after said separation process, wherein an optical sheet is disposed inside said frame body on each of said plurality of liquid crystal panels.

19. The manufacturing method for a liquid crystal display device according to claim 11, wherein said light source and said light guide plate are disposed on said mounting section formed in said formation process, with a light-emitting side of said light source and a light-receiving side of said light guide plate in contact with each other.

20. The manufacturing method for a liquid crystal display device according to claim 11, wherein a disposition process is conducted, in which a light-emitting diode as said light source is disposed on said mounting section formed in said formation process.
